(19) United States
(12) Patent Application Publication
(10) Pub. No.: US 2012/0071003 A1
(43) Pub. Date: Mar. 22, 2012

(54) Vacuum Processing Apparatus, Vacuum Processing Method, and Micro-Machining Apparatus

(76) Inventors: Kazuya Dobashi, Nirasaki City (JP); Takashi Fuse, Nirasaki City (JP); Satohiko Hoshino, Nirasaki City (JP); Takehiko Senoo, Osaka (JP); Yu Yoshino, Moriyama-shi (JP)

(21) Appl. No.: 13/233,150

(22) Filed: Sep. 15, 2011

(30) Foreign Application Priority Data
Sep. 17, 2010 (JP) 2010-209832

(51) Int. Cl. H01L 21/31; C23C 14/16; C23F 1/08; C23C 14/34; C23C 16/455; C23C 16/48

(52) U.S. Cl. 438/758; 118/719; 156/345.33; 204/298.02; 257/E21.24

(57) ABSTRACT

Disclosed is a technology in which a nozzle part is mounted in a vacuum chamber and a silicon substrate is held to face a discharge hole of the nozzle part. For example, ClF₃ gas and Ar gas are supplied from the nozzle part and the mixed gas is discharged from the nozzle part under a vacuum atmosphere. By doing this, the mixed gas is adiabatically expanded and the Ar atoms or ClF₃ molecules are combined, which become a gas cluster. The gas cluster is irradiated to the surface of the silicon substrate without being ionized and, as a result, the surface of the silicon surface becomes a porous state. Then, lithium is grown on the surface of the silicon substrate in a separate vacuum chamber 41 by sputtering without breaking the vacuum.

### CROSS-REFERENCE TO RELATED APPLICATIONS

This application is based on and claims priority from Japanese Patent Application No. 2010-209832, filed on Sep. 17, 2010, with the Japanese Patent Office, the disclosure of which is incorporated herein in its entirety by reference.

### TECHNICAL FIELD

The present disclosure relates to a technology of making a surface portion of a silicon substrate in a porous state under a vacuum atmosphere.

### BACKGROUND

A technology of performing nano-level micro-machining on a silicon substrate has recently drawn attention in various fields such as a thermoacoustic device, a solar cell, a bio substrate, or the like. As an example, the technology has been applied to the negative electrode material of a lithium ion secondary battery. Conventionally, carbon has been used for the negative electrode material of the lithium ion secondary battery. However, it has been required recently that the capacity of the lithium ion secondary battery be increased. As a result, silicon has drawn attention for the negative electrode material, instead of carbon, due to its higher capacity density than carbon, thereby achieving a higher capacity battery.

However, since silicon tends to expand its volume when silicon forms an alloy with lithium ions, several problems need to be overcome when silicon is used as a negative electrode material. For examples, problem of durability such as a breakage of a battery due to the expansion, and a deterioration of the negative electrode caused by the change in volume due to repetitive charging and discharging, needs to be overcome. Also, there is possibility that lithium is grown on the surface of silicon to achieve a high capacity battery. However, to this end, a high-quality lithium thin film needs to be grown so as to follow up the volume change of the silicon negative electrode at the time of charging and discharging. As a solving means of the durability problem, the porous machining is performed on the silicon substrate used for the negative electrode to form micro voids thereon, thereby absorbing the increased volume at the time of charging and mitigating the inner stress.

Generally, as a method of performing the porous machining on the substrate, an anode oxidation method has been known. However, since the anode oxidation method is performed under the situation in which the substrate contacts an electrolyte, the substrate is taken out under the atmosphere. For this reason, the surface of the silicon substrate may be oxidized by moisture or oxygen in the air, and polluted due to the attachment of impurities in the electrolyte or the electrode material and even impurities in the air. As a result, a clean surface of the silicon substrate required for the high-quality lithium growth in the subsequent process may not be obtained.

Japanese Patent Application Laid-Open No. 2006-231376 describes a method of performing nano-level micro-machining on the surface of the silicon substrate by a laser beam, but does not describe the above-mentioned problems.

### SUMMARY

An exemplary embodiment of the present disclosure provides a vacuum processing apparatus which includes: a first vacuum chamber having a first holding part disposed therein and configured to hold a silicon substrate; a nozzle part configured to adiabatically expand a processing gas having a pressure higher than a pressure in the first vacuum chamber by discharging the processing gas to the first vacuum chamber to form a gas cluster that is an aggregation of atoms or molecules of the processing gas and to irradiate the gas cluster to the silicon substrate held in the first holding part in order to make the silicon substrate to become a porous state; a second vacuum chamber connected to the first vacuum chamber through a partition valve and configured to have a second holding part disposed therein for holding the silicon substrate; a film forming processing part configured to perform a film forming processing under a vacuum atmosphere for the porous silicon substrate within the second vacuum chamber; and a vacuum transportation area including a transportation mechanism configured to transport the porous silicon substrate in the first vacuum chamber to the second vacuum chamber without breaking the vacuum atmosphere. In particular, the gas cluster is not ionized.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view showing the entire vacuum processing apparatus according to an exemplary embodiment of the present disclosure.

FIG. 2 is a longitudinal cross-sectional side view schematically showing a micro-machining apparatus used in the above-mentioned exemplary embodiment of the present disclosure.

FIG. 3 is a longitudinal cross-sectional view schematically showing a cluster nozzle.

FIG. 4 is a longitudinal cross-sectional side view schematically showing a film forming apparatus.

FIG. 5 is an explanation view schematically showing a process of manufacturing a negative electrode material according to the exemplary embodiment of the disclosure.

FIG. 6 is an explanation view showing an example of a method of irradiating a gas cluster to the silicon substrate according to the exemplary embodiment of the present disclosure.

FIG. 7 is a longitudinal cross-sectional side view showing a micro-machining apparatus according to a modified example of the above-mentioned exemplary embodiment of the present disclosure.

FIG. 8 is a longitudinal cross-sectional view showing a silicon substrate that is machined using the micro-machining apparatus according to the modified example of the above-mentioned exemplary embodiment of the present disclosure.

FIG. 9 is a longitudinal cross-sectional side view showing a portion of a micro-machining apparatus according to the modified example of the above-mentioned exemplary embodiment of the present disclosure.

FIG. 10 is a longitudinal cross-sectional side view schematically showing a vacuum processing apparatus according to another exemplary embodiment of the present disclosure.

FIG. 11 is an SEM photograph of the surface of a silicon substrate after the porous machining according to the exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

The present disclosure has been made in an effort to provide a technology of making a surface portion of a silicon substrate to become a porous state by micro-machining and maintaining the surface portion thereof in a high clean state.

An exemplary embodiment of the present disclosure provides a vacuum processing apparatus includes: a first vacuum chamber having a first holding part disposed therein and configured to hold a silicon substrate; a nozzle part configured to adiabatically expand a processing gas having a pressure higher than a pressure in the first vacuum chamber by discharging the processing gas to the first vacuum chamber to form a gas cluster that is an aggregation of atoms or molecules of the processing gas and to irradiate the gas cluster to the silicon substrate held in the first holding part in order to make the silicon substrate in a porous state; a second vacuum chamber connected to the first vacuum chamber through a partition valve and configured to have a second holding part disposed therein for holding the silicon substrate; a film forming processing part configured to perform a film forming processing under vacuum atmosphere for the porous silicon substrate within the second vacuum chamber; and a vacuum transportation area including a transportation mechanism configured to transport the porous silicon substrate in the first vacuum chamber to the second vacuum chamber without breaking the vacuum atmosphere. In particular, the gas cluster is not ionized.

In the above vacuum processing apparatus, the vacuum transportation area is a vacuum transportation chamber connected to the first vacuum chamber and the second vacuum chamber, respectively, through partition valves, and the transportation mechanism is operated to perform the transportation from the first vacuum chamber to the second vacuum chamber through the vacuum transportation chamber.

In the above vacuum processing apparatus, the film forming processing part performs a sputtering for attaching metal to the silicon substrate.

Another exemplary embodiment of the present disclosure provides a vacuum processing method, including: holding a silicon substrate by a holding part within a vacuum chamber; and forming a gas cluster that is an aggregation of atoms or molecules of a processing gas in the vacuum chamber by adiabatic expanding of the processing gas by discharging the processing gas having a pressure higher than a pressure within the vacuum chamber from a nozzle part to the vacuum chamber, and irradiating the gas cluster to the silicon substrate while maintaining the gas cluster not being ionized thereby making the silicon substrate to be a porous state.

The above vacuum processing method further comprises, after making the silicon substrate to become a porous state, performing the film forming processing on the silicon substrate without breaking the vacuum in the atmosphere where the silicon substrate is located.

Yet another exemplary embodiment of the present disclosure provides a micro-machining apparatus, including: a first vacuum chamber having a first holding part disposed therein and configured to hold a silicon substrate; and a nozzle part configured to adiabatically expand a processing gas having a pressure higher than a pressure in the first vacuum chamber by discharging the processing gas to the first vacuum chamber to form a gas cluster that is an aggregation of atoms or molecules of the processing gas and to irradiate the gas cluster to the silicon substrate held in the first holding part in order to make the silicon substrate to become a porous state. In particular, the gas cluster is not ionized.

The exemplary embodiment of the present disclosure makes the surface portion of the silicon substrate to become the porous state by the micro-machining using the gas cluster under the vacuum atmosphere, such that the surface portion thereof may be maintained at a high clean state since there is no risk of oxidation of the silicon or the attachment of the residue of impurities. The deterioration in the grown machined product may be suppressed and the desired material characteristics may be obtained by continuously processing the film forming on the surface portion thereof under the vacuum atmosphere.

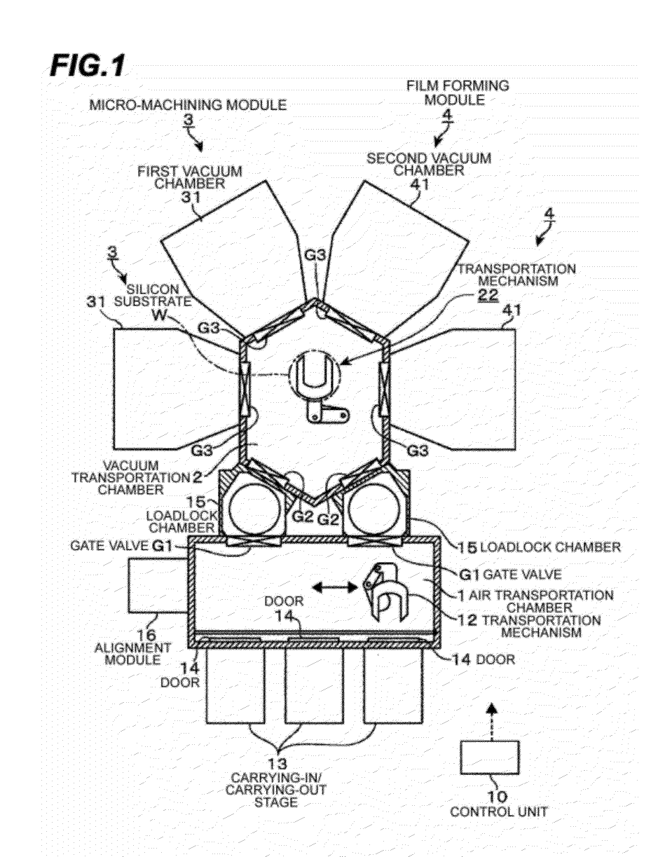

A vacuum processing apparatus 7 according to an exemplary embodiment of the present disclosure includes an air transportation chamber 1 having a rectangular shape as viewed from above, as shown in FIG. 1. One long side of air transportation chamber 1 is provided with a carrying-in/out port 11 for carrying-in/out a silicon substrate W formed in a silicon substrate form, e.g., a circular wafer form. Carrying-in/out port 11 includes a plurality of carrying-in/out stages 13 in which a transportation vessel 12 made of, for example, FOUP that receives plural silicon substrates W and a door 14 that is provided on each carrying-in/out stage 13.

In air transportation chamber 1, an opposite side of carrying-in/out stages 13 is connected to a vacuum transportation chamber 2 configuring a vacuum transportation area, which is, for example, a hexagon shape when viewed from above, through two load-lock chambers 15 (reserved vacuum chambers) disposed left and right, respectively. Further, a short side thereof is connected with an alignment module 16 that includes an orienter for aligning silicon substrates W. Air transportation chamber 1 is provided with a transportation mechanism 12 that transfers silicon substrate W among carrying-in/out stages 13, load-lock chambers 15 and alignment module 16.

The inside of vacuum transportation chamber 2 is maintained under the vacuum atmosphere by a vacuum pump (not shown), and a first vacuum chamber 31 configuring the processing atmosphere of a micro-machining module 3 and a second vacuum chamber 41 configuring the processing atmosphere of a film forming module 4 are connected to vacuum transportation chamber 2. Vacuum transportation chamber 2 includes a transportation mechanism 22 that is configured of a rotating flexible transportation arm for transferring silicon substrate W among load-lock chambers 15, alignment module 16, micro-machining module 3 and film forming module 4. In FIG. 1, G1 to G3 are gate valves that form partition valves.

Vacuum processing apparatus 7 includes a control unit 10, and the transportation of silicon substrate W, the opening and closing of each gate valve G1 to G3 and door 14, and the processing and vacuum degree of each vacuum chamber 31 and 41 are controlled by software including a program and a processing recipe that are stored in the storage unit of control unit 10.

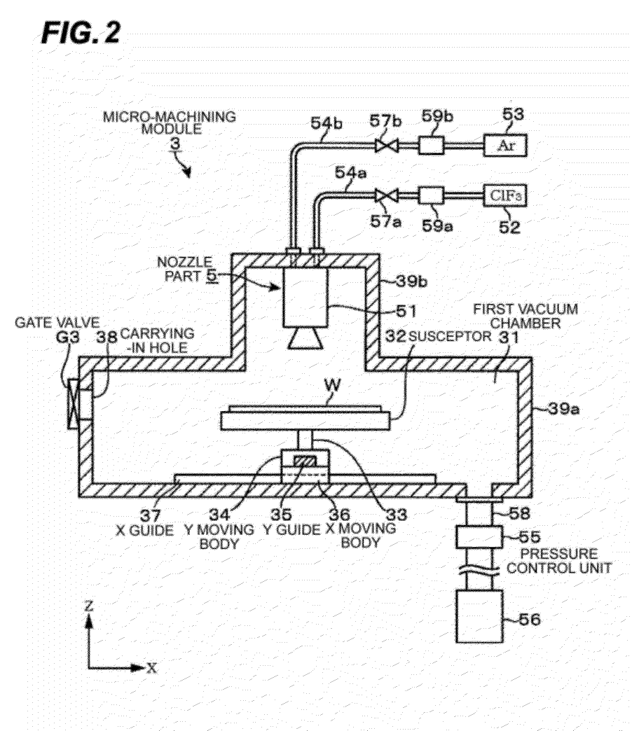

As shown in FIG. 2, first vacuum chamber 31 of micro-machining module 3 is provided with a flat cylindrical part 39a and a small cylindrical part 39b having a smaller diameter than that of cylindrical part 39a. Small cylindrical part 39b is protruded upwardly at the top central portion of flat cylindrical part 39a. First vacuum chamber 31 is provided with a susceptor 32 that is a first holding part for arranging and holding silicon substrate W in a horizontal direction. Susceptor 32 is elevated by an elevation mechanism (not shown) and silicon substrate W transported through a carrying-in hole 38 by transportation mechanism 22 may be held through support pins (not shown).

Susceptor 32 embeds a temperature control unit (not shown), which can control the temperature of silicon substrate W. A bottom portion of first vacuum chamber 31 is provided with an X guide 37 horizontally extending in an X direction and is provided with an X moving body 36 that moves while being guided by X guide 37. The top of X moving body 36 is provided with Y guide 35 horizontally extending in a Y direction (a front and back direction of the paper sheet) and is provided with a Y moving body 34 that moves while being guided by Y guide 35. Susceptor 32 may be mounted through a support member 33 on Y moving body 34 and thus, may move in the X and Y directions. Describing only X guide 37 and Y guide 35, a ball screw mechanism that may move while controlling the position at high precision in the X and Y directions is mounted and the description thereof is omitted in the drawings.

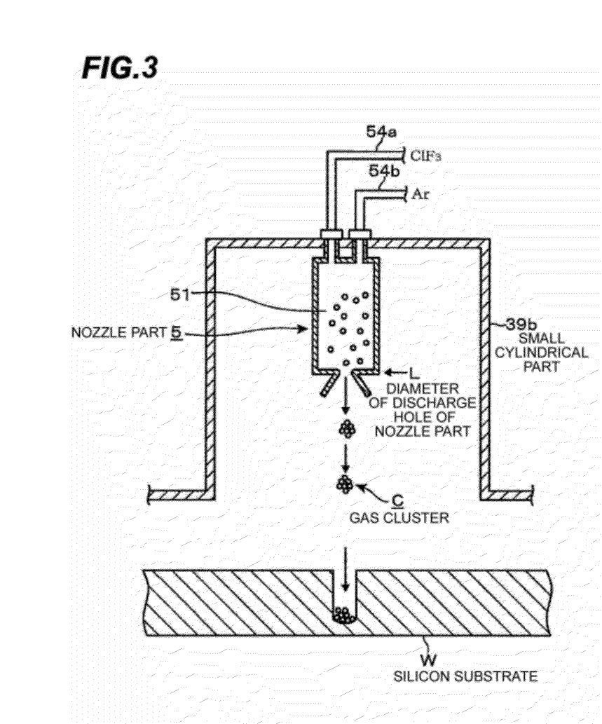

The ceiling of micro-machining module 3 is provided with a nozzle part 5 so as to be opposite to silicon substrate W disposed as shown in FIGS. 2 and 3. Nozzle part 5 includes a cylindrical pressure chamber 51, and a base end of nozzle part 5 is connected to a first gas passage 54a and a second gas passage 54b that are configured of pipe, respectively. The base end of first gas passage 54a is connected to a ClF₃ gas supply source. For example, a flow control unit 59a configured of a mass flowmeter and a valve 57a are interposed between the base end of first gas passage 54a and ClF₃ gas supply source. The base end of second gas passage 54b is connected to an Ar gas supply source. For example, a flow control unit 59b configured of a mass flowmeter and a valve 57b are interposed between the base end of second gas passage 54b and Ar gas supply source. Although not shown, a pressure gauge detecting the pressure in pressure chamber 51 is mounted to control the pressure in pressure chamber 51 and a flow ratio of ClF₃ gas and Ar gas by flow control units 59a and 59b and the pressure gauge.

A lead end of nozzle part 5 is spread in a horn shape and a distance from a source portion (discharge hole) of the spreading part to silicon substrate W may be set to be, for example, 6.5 mm and the discharge hole of nozzle part 5 is formed in an orifice shape having a diameter of, for example, 0.1 mm As described below, the gas discharged from nozzle part 5 is adiabatically expanded by being exposed to the abruptly reduced pressure and the atoms or molecules of the processing gas are coupled by van der Waals' force to form aggregation (gas cluster) C to be irradiated to silicon substrate W. The bottom portion of first vacuum chamber 31 is connected to an exhaust pipe 58, and exhaust pipe 58 is provided with vacuum pump 56 having pressure control unit 55 disposed therebetween, therefore the pressure in first vacuum chamber 31 can be controlled. In order to easily control the pressure around the discharge hole of nozzle part 5, a side of small cylindrical part 39b in a cylindrical tube shape may be provided with a vacuum pump. Nozzle part 5 is controlled to make the axial direction thereof to be orthogonal to silicon substrate W so that irradiated gas cluster C vertically contacts silicon substrate W on susceptor 32.

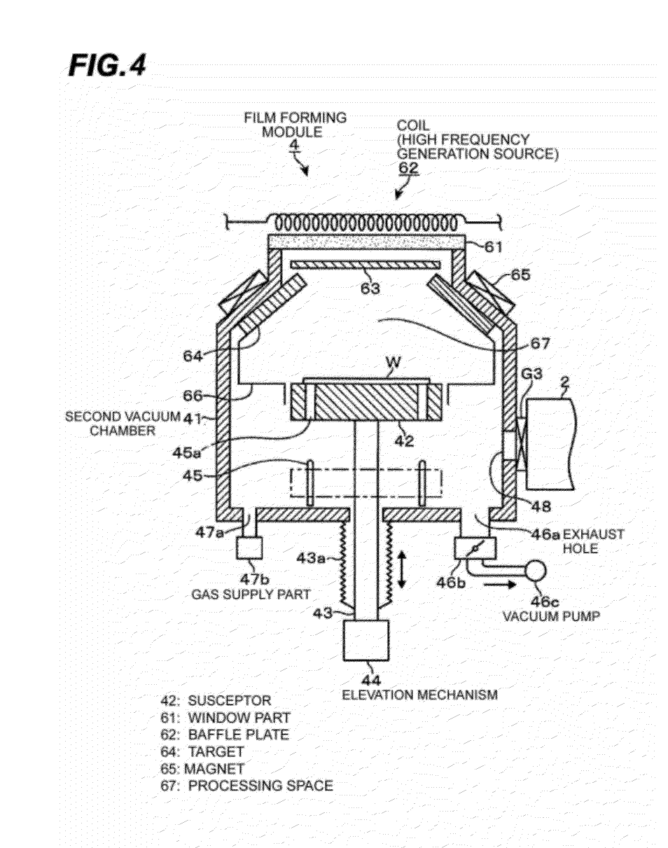

Film forming module 4 includes second vacuum chamber 41 configured of a cylindrical processing vessel as shown in FIG. 4. Second vacuum chamber 41 is grounded and is equipped with a vacuum pump 46c having a pressure control unit 46b disposed therebetween from an exhaust hole 46a formed on the bottom portion of second vacuum chamber 41.

Second vacuum chamber 41 is equipped with a disk-shaped susceptor 42. Susceptor 42 may adsorb and hold silicon substrate W by electrostatic force at the top of susceptor 42 and may apply predetermined bias power for inputting ions. The inside of susceptor 42 is provided with the temperature control unit and the temperature of silicon substrate W held on susceptor 42 may be controlled. Susceptor 42 is supported by a support member 43 that extends downwardly from the bottom central portion thereof, and support member 43 may be elevated by an elevation mechanism 44. Reference numeral 43a represents a bellows.

The bottom of second vacuum chamber 41 is provided with, for example, three support pins 45 standing upwardly, and susceptor 42 is provided with pin insertion through holes 45a corresponding to support pins 45, respectively. By doing this, when susceptor 42 moves downwardly, support pins 45 are protruded above susceptor 42 by penetrating through pin insertion through holes 45a. For this reason, silicon substrate W held on susceptor 42 is lifted by the top end of support pins 45. Therefore, the silicon substrate may be transferred between transportation mechanism 22 entered from transportation hole 48 at the lower side wall of second vacuum chamber 41. G3 is a gate valve that is a partition valve.

The ceiling portion of second vacuum chamber 41 is provided with a window part 61 that is made of a dielectric material. Reference number 62 represents a coil that is a high frequency wave generation source, and reference numeral 63 represents a baffle plate that spreads the high frequency wave. The bottom of baffle plate 63 is provided with a target 64, for example, made of lithium in an annular shape while, for example, a cross section being inwardly inclined to surround the top side of a processing space 67. Target 64 may be supplied with voltage for attracting Ar ion. The outer peripheral side of target 64 is provided with a magnet 65 for providing a magnetic field thereto. Reference numeral 66 is a protective cover.

Plasma excitation gas, for example, Ar gas or other necessary gases, for example, N₂ gas is supplied from a gas supply part 47b via a gas introducing hole 47a that is disposed at the bottom portion of second vacuum chamber 41. Target 64, coil 62 that is a high frequency wave generation source, and gas supply part 47b correspond to a film forming processing part.

Continuously, the operation of the above-mentioned exemplary embodiment will be described. First, transportation vessel 12 made of, for example, FOUP, which receives silicon substrates W, is disposed at carrying-in/out stage 13 and door 14 is opened together with the cover of transportation vessel 12. Thereafter, silicon substrate W in transportation vessel 12 is transferred to alignment module 16 by transportation mechanism 12 in air transportation chamber 1, the orientation of silicon substrate W is controlled in a predetermined direction at alignment module 16. Thereafter, silicon substrate W is carried-in to susceptor 32 of first vacuum chamber 31 of micro-machining module 3 through transportation mechanism 12, load-lock chamber 15, and transportation mechanism 22 in vacuum transportation chamber 2.

Continuously, first vacuum chamber 31 is maintained in the vacuum atmosphere of, for example, 1 Pa to 100 Pa by pressure control unit 55, and each of the ClF₃ gas and the Ar gas is supplied to nozzle part 5 from a gas passage 54, by, for example, pressure control units 57a and 57b at a pressure of 0.3 MPa to 2.0 MPa. The flow ratio of the ClF₃ gas to the Ar gas is set to be, for example, 0.5% to 20% by flow control units 59a and 59b. As described above, since the ClF₃ gas and the Ar gas supplied to nozzle part 5 in a high pressure state are instantly discharged to the vacuum atmosphere of first vacuum chamber 31 from nozzle part 5, the ClF₃ gas and the Ar gas are adiabatically expanded to set the gas temperature to a condensation temperature, or less. In this example, the ClF₃ molecule and the Ar atom are coupled by the van der Waals' force to form gas cluster C that is the aggregation of atoms and molecules.

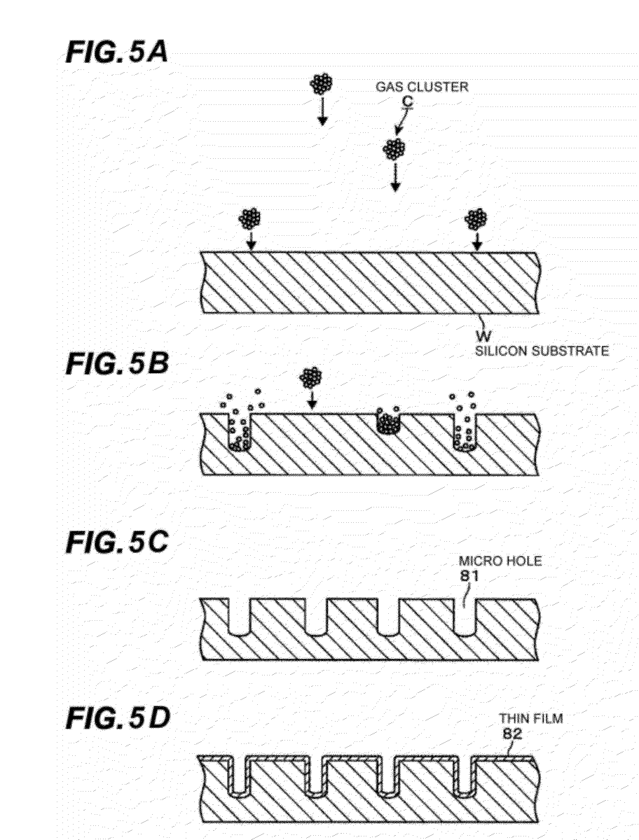

Gas cluster C is straightly discharged in the axial direction of nozzle part 5 from nozzle part 5 and vertically collides towards silicon substrate W as shown in FIGS. 5A and 5B. As described above, straightly discharging gas cluster C in the axial direction of nozzle part 5 is confirmed in the experiment to be described below. For this reason, as shown in FIG. 5C, the surface portion of silicon substrate W is hollowed out by gas cluster C to form aperture parts 81 and becomes porous state. In this case, the silicon particles are scattered from the surface portion of silicon substrate W, but are exhausted through exhaust pipe 58, together with the atoms or molecules of gas decomposed by colliding with the silicon substrate. Meanwhile, FIG. 5 is an image diagram in which silicon substrate W becomes porous state by gas cluster C.

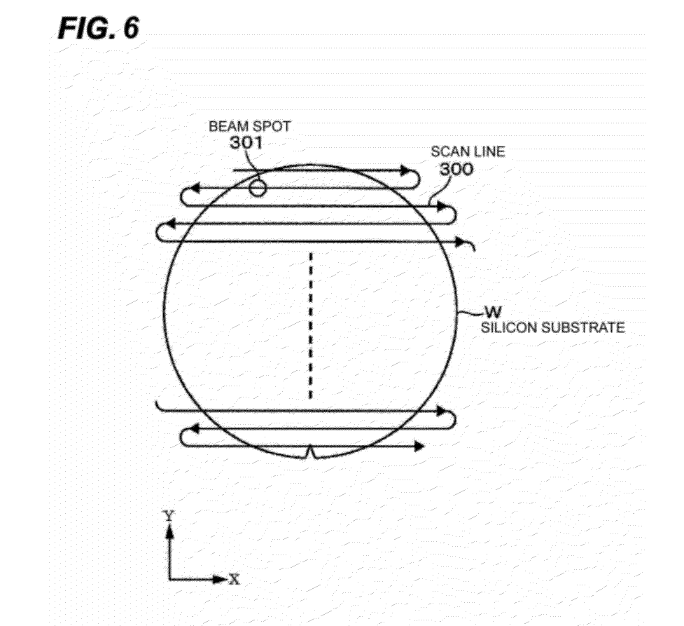

This is a state in which a beam of, for example, 0.5 mm to 5 mm is macroscopically irradiated to silicon substrate W from nozzle part 5, and a beam spot 301 is relatively scanned to silicon substrate W by moving susceptor 32. The scanning method scans beam spot 301 from one end side of silicon substrate W along a scan line 30 in an X direction as shown in, for example, FIG. 6. Then, there may be a method of scanning the entire surface of silicon substrate W without stopping by moving beam spot 301 by a predetermined distance in the Y direction, and moving from the end of silicon substrate W to the other end thereof. In this case, as the relatively moving timing of beam spot 301, there may be, for example, a method for intermittently and sequentially moving beam spot 301 by a radial dimension while, for example, irradiating and stopping the beam for the predetermined time at each position.

In the micro-machining process described above, the temperature of silicon substrate W may be at normal temperature. For the reason of the control performance of the processor, the temperature may be, for example, 0° C. to 100° C., but the temperature is not particularly limited thereto. As the processing gas, the gas is not limited thereto, but HF gas, F₂ gas, NH₄OH gas, or the like, may be used.

After the entire surface of silicon substrate W is micro-machined and becomes a porous state, gate valve G3 is opened and silicon substrate W is carried-out from first vacuum chamber 31 by transportation mechanism 22 of vacuum transportation chamber 2 so as to be carried in susceptor 42 of second vacuum chamber 41 of film forming module 4.

Silicon substrate W carried in second vacuum chamber 41 maintained in a vacuum state is transferred to support pins 45 and then, adsorbed and held to susceptor 42 elevated by elevation mechanism 44. After transportation hole 48 is sealed by gate valve G3, the Ar gas is supplied to second vacuum chamber 41 from gas supply part 47b and the inside of second vacuum chamber 41 is maintained at a predetermined vacuum degree by controlling pressure control unit 46b.

Thereafter, DC power is applied to target 64 made of lithium and high frequency power (plasma power) is further applied to plasma generation source 62. At the same time, silicon substrate W is controlled to be at the predetermined temperature at susceptor 42 by a heater (not shown) and the predetermined bias power is applied to susceptor 42. By doing this, the argon gas is changed to a plasma state by the plasma power applied to plasma generation source 62 to generate the argon ions. These ions collide with target 64 by being attracted to the voltage applied to target 64, and target 64 is sputtered to discharge the lithium (Li) particles. The lithium particles sputtered from target 64 are scattered downwardly in the state in which the lithium atoms that are electrically neutral are mixed with the ionized lithium ions. In particular, the pressure in second vacuum chamber 41 is maintained at, for example, about 0.67 mPa (5 mTorr), such that the plasma density is increased, thereby ionizing the lithium particles at high efficiency. When the lithium ions enter an area of an ion sheath having a thickness of about several mm on silicon substrate W generated by the bias power applied to susceptor 42, the lithium ions are attracted to be accelerated to silicon substrate W side while having directivity and thus, are deposited on silicon substrate W. As described above, a thin film 82 deposited by the lithium ions having a high directivity may have good coverage performance. FIG. 5D shows a state in which lithium thin film 82 is grown on the surface of silicon substrate W.

According to the above-mentioned exemplary embodiment, gas cluster C is formed under the vacuum atmosphere and is irradiated to silicon substrate W without ionizing gas cluster C. For this reason, an aperture part 81 meeting the size of gas cluster C is formed on the surface part of silicon substrate W and thus, is micro-machined, that is, become a porous state. The size of gas cluster C may be controlled by changing the pressure difference of the vacuum atmosphere and inside 51 of nozzle part 5, the flow ratio of the introduction gas, such as for example, the ClF₃ gas and the Ar gas, and the distance from the discharge hole of nozzle part 5 to silicon substrate W, therefore the size of aperture part 81 on the surface part of silicon substrate W may be readily controlled. Unlike the anode oxidation method which causes impurities in the electrolyte or electrode material polluting the surface of silicon substrate W, the porous surface of silicon substrate W is clean without impurities. After silicon substrate W is micro-machined (porous), the growth of the lithium is performed without breaking the vacuum atmosphere, such that lithium thin film 82 is formed on the porous surface without oxidizing the surface of silicon substrate W by air. As a result, a high-quality Li—Si negative material is obtained.

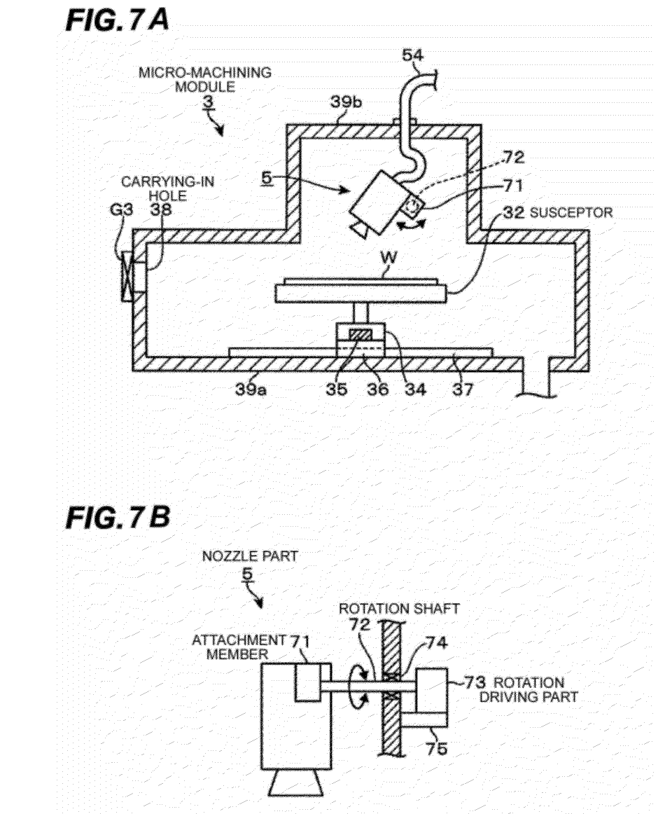

Next, modified example of the above-mentioned exemplary embodiment will be described. The irradiation direction of gas cluster C to silicon substrate W may be inclined rather than the vertical direction as in the above-mentioned example. As shown in FIG. 7, an example of the structure realizing the method may include a structure in which one end of a horizontal rotation shaft 72 is connected to an attachment member 71 fixed to nozzle part 5, and the other side of rotation shaft 72 extending to the outside of vacuum chamber 31 to connect to a rotation driving part 73 including a motor. In FIG. 7, reference numeral 74 represents a bearing part combining a magnetic seal, and reference numeral 75 represents a holding member fixed to a side wall of the small cylindrical part of vacuum chamber 3. A control signal of rotation driving part 73 is output from control unit 10 described in FIG. 1 to rotate nozzle part 5 about rotation shaft 72, thereby optionally setting the irradiation direction of gas cluster C from nozzle part 5 to the surface of silicon substrate W.

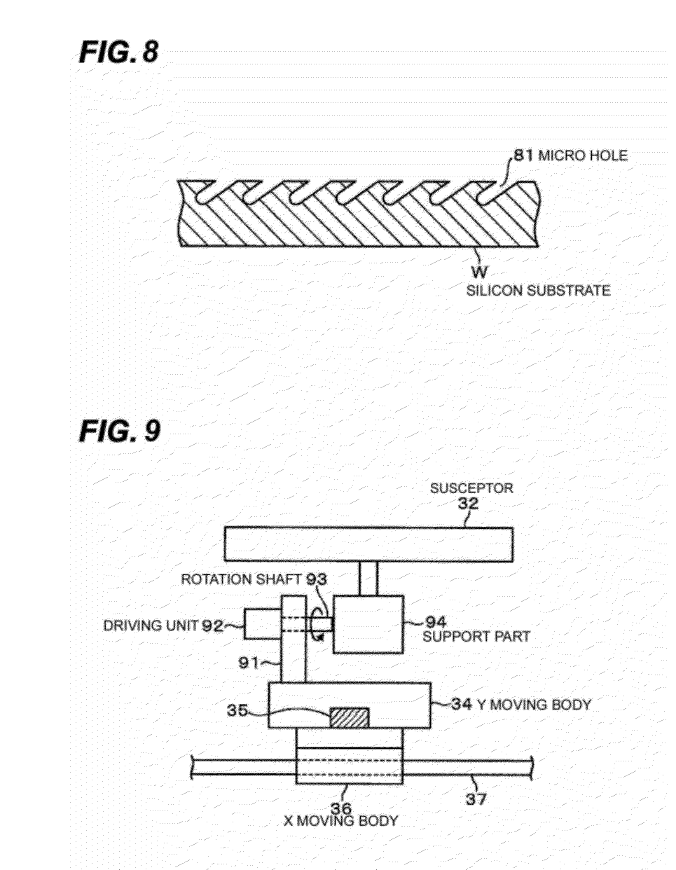

According to the above example, gas cluster C is obliquely incident to the surface of silicon substrate W, such that aperture part 81 is formed to be obliquely dented downwardly as shown in FIG. 8. Therefore, the range of aperture part 81 is more three-dimensional than the case of the above-mentioned embodiment. In other words, when being viewed from the transverse direction, a large number of voids may be present and the change in volume of silicon substrate W may be more endured. In order to obtain the effects, as shown in FIG. 9, susceptor 32 side may be formed to be inclined. In this example, an attachment member 91 is mounted on a Y moving body to be protruded upwardly, and a rotation driving part 92 including a motor is attached to attachment member 91. A lead end of a rotation shaft 93 rotating around a horizontal axis by rotation driving part 92 is mounted with a support part 94, and susceptor 32 is supported by support part 94. In this case, support part 94 rotates about rotation shaft 93 by the control signal of rotation driving part 92 output from control unit 10 as described in FIG. 1, thereby optionally setting the surface direction of silicon substrate W with respect to the axial line (extension line of the central line of nozzle part 5) of nozzle part 5.

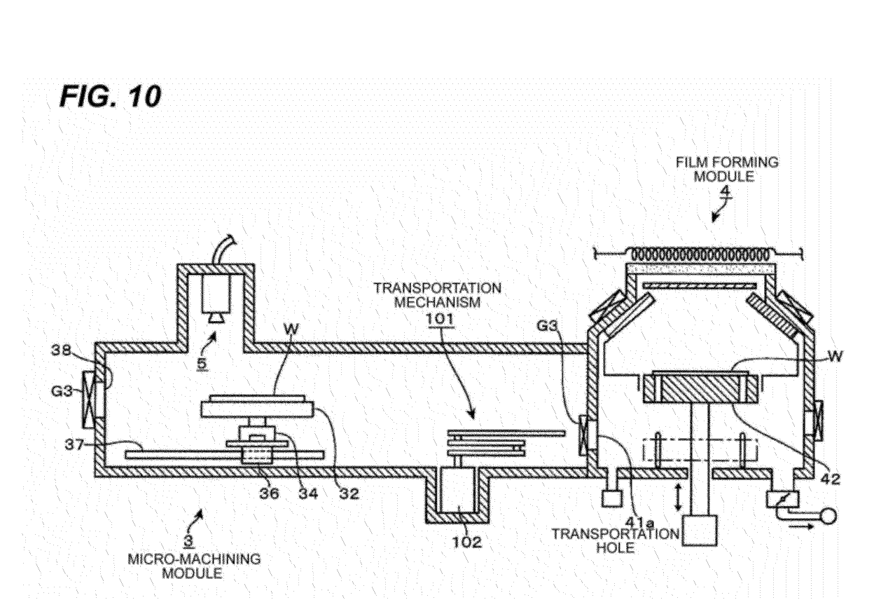

In the example of FIG. 1, in transporting the micro-machined (porous surface part) silicon substrate W into vacuum chamber 41 of film forming module 4, the vacuum transportation area is configured by vacuum transportation chamber 2, but the present disclosure is not limited to the above configuration, and, for example, may be configured as shown in FIG. 10. In the example of FIG. 10, first vacuum chamber 31 of micro-machining module 3 is directly connected to second vacuum chamber 41 of film forming module 4 through the partitioning valve, e.g., gate valve G3, and first vacuum chamber 31 is provided with an articulation arm type transportation mechanism 101 in which, for example, three arms are connected. Reference numeral 102 represents a driving part in which a retreat mechanism and an elevation mechanism of the articulation arm are combined with each other. In this case, transportation mechanism 101 receives micro-machined silicon substrate W by gas cluster C from susceptor 32 to transfer silicon substrate W to susceptor 42 through transportation hole 41a of second vacuum chamber 41 opened by opening gate valve G3. Thereafter, silicon substrate W is subjected to the lithium sputter film forming processing in vacuum chamber 41 as described above.

Alternatively, transportation mechanism 101 as shown in FIG. 10 may be mounted at second vacuum chamber 41. In this case, in FIG. 10, a vertical partition wall partitioning the micro-machined processing atmosphere by gas cluster C and the lithium sputter processing atmosphere is disposed at the left of transportation mechanism 101, and the partition wall is provided with the transportation hole and the gate valve.

In addition to the lithium, for example, titanium oxide (TiO₂) or gold (Au) may be grown on porous silicon substrate W and may be used as a catalyst. The present disclosure may be used for manufacturing the substrate in a biotechnology field and fixing the specific protein by adsorbing a functional material, for example, a silane coupling agent to porous silicon substrate W.

### Example

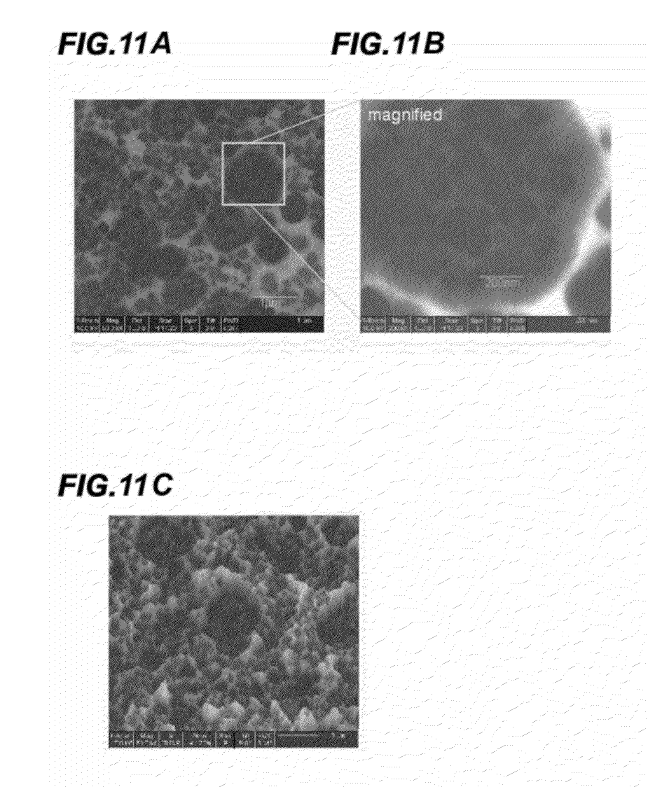

Gas cluster C was irradiated to the surface portion of silicon substrate W by using the apparatus shown in FIG. 2, using the ClF₃ gas and the Ar gas as the processing gas, setting the pressure of 0.8 MPa in the nozzle part, setting the atmosphere of the vacuum chamber to 10 Pa, setting the distance from the discharge hole of nozzle part 5 to silicon substrate W to 6.5 mm FIG. 11 shows the observation results observing the surface of silicon substrate W by the SEM, wherein it was appreciated that aperture part 81 having a diameter of at least about 20 nm to 50 nm is formed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A vacuum processing apparatus, comprising:
a first vacuum chamber having a first holding part disposed therein and configured to hold a silicon substrate;
a nozzle part configured to adiabatically expand a processing gas having a pressure higher than a pressure in the first vacuum chamber by discharging the processing gas to the first vacuum chamber to form a gas cluster that is an aggregation of atoms or molecules of the processing gas, and to irradiate the gas cluster to the silicon substrate held in the first holding part in order to make the silicon substrate to become a porous state;
a second vacuum chamber connected to the first vacuum chamber through a partition valve, and configured to have a second holding part disposed therein for holding the silicon substrate;
a film forming processing part configured to perform a film forming processing under a vacuum atmosphere for the porous silicon substrate within the second vacuum chamber; and
a vacuum transportation area including a transportation mechanism configured to transport the porous silicon substrate in the first vacuum chamber to the second vacuum chamber without breaking the vacuum atmosphere,
wherein the gas cluster is not ionized.

2. The vacuum processing apparatus of claim 1, wherein the vacuum transportation area is a vacuum transportation chamber connected to the first vacuum chamber and the second vacuum chamber, respectively, through a partition valve, and
the transportation mechanism is operated to perform the transportation from the first vacuum chamber to the second vacuum chamber through the vacuum transportation chamber.

3. The vacuum processing apparatus of claim 1, wherein the film forming processing part performs a sputtering for attaching metal to the silicon substrate.

4. A vacuum processing method, comprising:
holding a silicon substrate by a holding part within a vacuum chamber; and
forming a gas cluster that is an aggregation of atoms or molecules of a processing gas in the vacuum chamber by adiabatic expanding of the processing gas by discharging the processing gas having a pressure higher than a pressure within the vacuum chamber from a nozzle part to the vacuum chamber; and
irradiating the gas cluster to the silicon substrate while maintaining the gas cluster not being ionized thereby making the silicon substrate to be a porous state.

5. The vacuum processing method of claim 4, further comprising, after making the silicon substrate to become a porous state, performing a film forming process on the silicon substrate without breaking the vacuum in the atmosphere where the silicon substrate is located.

6. Micro-machining apparatus, comprising:
a first vacuum chamber having a first holding part disposed therein and configured to hold a silicon substrate; and
a nozzle part configured to adiabatically expand a processing gas having a pressure higher than a pressure in the first vacuum chamber by discharging the processing gas to the first vacuum chamber to form a gas cluster that is an aggregation of atoms or molecules of the processing gas, and to irradiate the gas cluster to the silicon substrate held in the first holding part in order to make the silicon substrate to become a porous state,
wherein the gas cluster is not ionized.
